(19) United States
(12) Patent Application Publication
(10) Pub. No.: US 2010/0018572 A1
(43) Pub. Date: Jan. 28, 2010

(54) Connection Box

(75) Inventors: Thomas Grimberg, Winterthur (CH); Martin Stucki, Pfaffikon (CH)

Correspondence Address: PAULEY PETERSEN & ERICKSON, 2800 WEST HIGGINS ROAD, SUITE 365, HOFFMAN ESTATES, IL, 60169, US

(73) Assignee: HUBER+SUHNER AG

(21) Appl. No.: 12/308,911

(22) PCT Filed: Jun. 19, 2007
(86) PCT No.: PCT/CH2007/000299

§ 371 Date: Aug. 24, 2009

(30) Foreign Application Priority Data
Jun. 29, 2006 (CH) 1056/06

(51) Int. Cl. H01L 31/00; H02G 3/08; H05K 5/00; H05K 7/20

(52) U.S. Cl. 136/252; 174/50; 174/520; 174/547

(57) ABSTRACT

A connection box (1) suited for wiring one or more solar cells (33) includes a housing base (2) and a housing top (3) that includes retaining means (21) for receiving a circuit board.

The present invention is in the field of connection technology, and relates to a connection box for connecting wiring to a device, in particular for connecting wiring to a photovoltaic module (photovoltaic collector, solar panel, solar cell).

Photovoltaic solar systems are usually modular in structure and consist of a large number of solar cells, which are connected via external wiring. In order to achieve a higher voltage, the individual solar cells are at least group-wise connected in series, in that the positive pole of a first solar cell is connected to the negative pole of at least one further solar cell. A problem here is that in a partial covering of a solar cell, e.g. because a shadow is cast by surrounding objects or by clouds, this solar cell becomes passive and contributes little or nothing to the current production. As a result, current from the adjacent solar cell passes in a series circuit through the covered solar cell, which may be damaged by this or at least have its lifetime reduced. For this reason, it is known that solar cells are temporarily bridged, and thus uncoupled from the current production during the interruption, by means of an electronic circuit, which usually has diodes as protective elements. These electronic circuits are often housed in connection boxes, which serve simultaneously for the connection of the wiring.

EP999601 from Sumitomo Wiring Systems Ltd shows a connection box for solar cells with a housing with a lower and an upper cover, which can be connected to each other with plug-in connections. The upper cover has connectors for external electrical wiring, and electrical plugs which are disposed in such a way that with the housing in the closed position they produce an electrical connection with corresponding electrical contacts of the lower cover. In the upper cover diodes are disposed, which serve for protection of the solar cells. To make the arrangement weather-proof, a filler material, e.g. silicone, is poured around the diodes. A particular disadvantage of this arrangement is that it is not suitable for present-day high-performance solar cells, as they have only inadequate cooling. A further disadvantage is that the suggested pouring in of silicone increases the material consumption and the weight unnecessarily, and is time-consuming. A further disadvantage is that in the event of a defect, the replacement of the electrical circuit involves a relatively high expense. The construction requires that the entire upper cover must be replaced, because the electronic components are not accessible and accordingly cannot be exchanged individually.

U.S. Pat. No. 6,582,249 from Tyco Electronics AMP GmbH shows a connection box for solar modules with a housing of plastic and a lid connected with a joint hinge. The housing base has an opening for connectors of a solar panel and connectors for external electrical wiring. Electrical components, e.g. diodes, are fitted in the housing base between the connectors. The electrical components can be protected against touch by a protective cover fitted with a hinge on the side inner wall of the housing. The components are preferably surrounded through an opening in the protective cover with a filler material, after the protective cover was fixed in the housing in the position for the intended purpose.

EP1605554 from Mantenimiento Instalaciones Malaga SL shows a connection box for solar cells with a housing base and a lid with separable plug-in connection. The housing has a first opening for connectors of a solar cell and a second opening for connectors for external electrical wiring. A printed circuit board can be attached in the housing with a screw.

The German utility model DE202005018884U1 from Multi-Holding AG shows a connection box for a solar panel. The connection box has a housing base and a lid, which is connected by a hinge on the housing base. The housing base has an opening for connectors of a solar panel and external electrical wiring. Contact elements for attaching electrical components, in particular diodes, are provided inside the housing. The contact elements are developed such that they should absorb and remove the heat resulting from the diodes.

EP1501133 from Tyco Electronic AMP GmbH shows a connection box for a solar panel. The connection box has a housing base and a lid connected to the housing base, swiveling round a hinge. The housing base has an opening in the bottom for connectors of a solar panel, and openings in a side wall for external electrical wiring. Conductor rails and contact elements are disposed inside the housing. One embodiment has a printed circuit board with diodes, which are held by retaining elements of the housing.

JP20022359389 from Kitani Denki K K shows a connection box for solar cells with a housing with a housing base and a removable lid. Openings in the bottom area of the housing base serve for connection to a solar panel. Openings in a side wall serve for connection of electrical wiring. Exchangeably disposed diodes serve as protective elements.

DE102005044939 from Spelsberg Guenther GmbH Co KG discloses a connection box for solar cells. The connection box has a protection facility e.g. in the form of a bypass diode. The printed circuit board is connected to a heat sink, which in order to remove heat is protruding from the housing, and is connected to the frame of the solar panel.

Connection boxes known from prior art often have the problem that they are complicated to install. A disadvantage is that the cables are permanently connected to the housing base. A further disadvantage is that maintenance is not easy and components cannot easily be exchanged, as the components are embedded. Further problems arise as a result of insufficient cooling. Here too there is a problem in that pouring in an insulating material does provide a certain resistance against environmental conditions, but the disadvantage of insufficient cooling must also be accepted. The housings known from prior art for connection boxes are likewise not suitable for use in restricted spaces, as fitting of the lid is not possible, or the lid is permanently connected by a hinge to the housing base, and thus in some circumstances cannot be opened wide enough at all. If a solar cell has to be exchanged with conventional wiring, this generally means that the entire installation has to be deactivated.

An object of the invention is to show a connection box which does not have the problems attached to prior art. A further object of the invention is to show a connection box with a modular structure, which enables a flexible construction and placement of components according to needs, so that differing requirements can be taken into account. A further object of the invention is to show an improved connection box for solar cells, which is suitable in particular for fitting on an underside of a solar cell and in restricted spaces.

The object is achieved with the invention defined in the claims.

A connection box according to the invention usually has a housing base and a housing top (lid), to which a separable effective connection can be made with the housing base. The housing base normally has a pedestal, which serves for fitting the connection box on a surface, e.g. a solar cell. External cables are usually connected with plugs, clamping elements or directly e.g. with solder joints preferably to the housing top, which if necessary contains a circuit board with electrical or electronic components or a support element for electrical or electronic functional units or components, e.g. a plastic plate. Contact elements and/or plug-in connections form an effective electrical connection between the housing top and the housing base, which is e.g. fitted on the reverse side of a solar cell and electrically connected to this. Between the housing base and the housing top a seal can be provided, which hermetically closes at least certain areas of the housing, so that no moisture can penetrate. Certain areas of the housing can be actively or passively cooled, in order e.g. to remove waste heat resulting from the diodes. The housing base and/or the housing top can have multiple subdivisions, certain of which can be hermetically isolated or cooled. This can be effected e.g. with intermediate floors or additional secondary internal housing/walls.

In one embodiment the top of the lid has protruding pivot studs in the rear area, which engage with corresponding bearing openings in the housing base in the closed position. The pivot studs are preferably developed such that the housing top can be removed from the housing base, if the housing top was partially raised at least in one area. On the opposite front area and/or to the side, the housing top has further means of effective connection, by which means the housing top can be effectively connected, preferably separably, to the housing base. In one embodiment the housing top has protruding snap hooks, which engage with corresponding openings of the housing base when the housing top is closed, and lock it securely. The snap hooks can be disposed in such a way that the housing of the connection box cannot be opened without a tool which is provided/developed specifically for this purpose. Other means of effective connection can be provided alternatively or in supplement, according to the application area. For example, it is possible to secure the housing parts with screws and/or to provide one time seals, or locking pins, which have to be replaced each time the housing is opened. It is further possible to arrange the snap hooks of the housing top in such a way that they break on opening and thus indicate an opening. In this case the lid usually has to be replaced for each opening.

The housing top in one embodiment is developed such that it is suitable for receiving a circuit board with an electronic circuit or electrical components. For this purpose the housing top has retaining means, in which the circuit board can be set separably or inseparably. Alternatively or in addition, the circuit board is glued or welded in place, so that separation from the housing top is not possible. In this case, the housing top must be exchanged with the circuit board in the event of a defect in the circuit board. The housing top and the circuit board preferably form one unit, which for example has separate cable connection apparatus. This means it is possible for the circuit board and/or the housing top to be electrically connected and prepared, with cables detached from the housing base of the connection box, which e.g. is already fitted on a surface of a solar cell, before the unit consisting of housing top and circuit board are set into the housing base. A cavity between the housing base and the housing top and/or the circuit board can be hermetically closed with a seal, so that plug-in connections and/or electrical components are shielded from environmental conditions.

In one embodiment the circuit board has first electrical contacts on the side facing the housing base, which are disposed such that when the housing is closed they interact with corresponding second electrical contacts of the housing base, in order e.g. to establish an effective connection with the electronic circuit of the circuit board. This electronic circuit or the electrical components can be disposed on the other side of the circuit board inside the housing top, where they are protected from outside influences on the one hand, and where on the other hand a dissipation of heat away from the solar cell can more easily be implemented. Depending on the application area, the housing top can have openings, which serve for example for heat dissipation or for cooling of the circuit board and the components fitted on it. The circuit board can furthermore be designed as a thermal separation or isolation element, in that the circuit board reduces the heat transfer from the solar cell to the electrical circuit or the electrical components, or to the reverse heat transfer. Other thermal separation elements are possible, e.g. a support element of plastic. In a preferred embodiment, the housing top has cooling openings which are disposed such that a cooling medium (e.g. air) can actively or passively flow through the housing and along the circuit board. At least areas of the circuit board can be developed as cooling elements for this purpose, or be designed with further cooling elements e.g. in the form of cooling fins. Alternatively or in supplement, at least one of the housing parts can be developed as a cooling element. If necessary, at least certain electrical elements are insulated, so that e.g. moisture penetrating through the cooling opening does not lead to a short circuit or the danger of a shock. Good results are obtained with an insulating protective lacquer (e.g. silicone-based).

The housing top and/or the housing base usually have the possibility of connecting by cable to the connection box or to electrical or electronic components or subassemblies in the interior of the connection box. In a preferred embodiment, the housing top has a cable opening, which serves for leading a cable through to the interior. The cable opening can be developed as a clamp, so that it has a clamping effect on the cable when the housing is closed, thereby protecting the cable from unwanted moving or withdrawal. The cable led into the interior of the housing can be effectively connected directly on the circuit board or with another means. One advantage of the cable connections in the area of the housing top is that the cables can be separately effectively connected to the housing top or to the circuit board.

The housing base and the housing top are preferably manufactured by injection molding from plastic. Any seals present are inserted or sprayed on with a multi-injection molding process.

One embodiment of the invention comprises a connection box with a housing base and a housing top which can be effectively connected to this and which has retaining means for receiving a circuit board, wherein the housing top can have means for connecting external wiring. The housing base usually has a pedestal, which serves for fitting the connection box on a flat and/or curved surface. Alternatively or in supplement, the housing base has effective connection means, with which the housing base can be effectively connected if necessary to a further part, e.g. a base plate. As effective connection means, snap and/or dovetail connections can be provided, for example, which enable a separable or inseparable effective connection. The base plate in turn can be developed as a mounting plate. An advantage of this is that especially in restricted spaces, the base plate can be fixed first. Then the housing base, which is suitable for receiving the housing top, can be effectively connected to the base plate.

The retaining means for receiving the circuit board can consist of a support, a relief cut and/or snap elements. Both the housing base and the housing top are essentially saucer-shaped, e.g. developed with one side open, so that in the closed state the connection box has one continuous interior space (cavity). If necessary the circuit board essentially extends across the entire width of the open side of the housing top, or the interior of the connection box. The circuit board can be disposed between the housing base and the housing top. Between the circuit board and the housing top and/or the housing base, a seal can be/is disposed. In a preferred embodiment, the housing top and the housing base form a modular unit. The circuit board can be equipped with electrical and/or electronic components. The housing base can have an opening for receiving electrical connectors, e.g. of a solar cell, the opening preferably being fitted in the housing bottom. If necessary the opening and/or a part of the interior space of the housing base can be filled at least partially with a filler material such as silicone or glue, provided neither the cooling of the connection box or its modular elements nor the interaction of the housing base with the housing top, i.e. the closing of the connection box, is impaired. The circuit board can interact with the housing base through first and second electrical contacts, which make an effective connection with the housing base when the housing top is closed.

Further embodiments are possible, in which a circuit board is set in the housing top and/or housing base.

Embodiments of the invention will be explained in more detail with reference to the figures that follow. Shown are:

FIG. 1 a connection box in a perspective representation from obliquely in front and above;

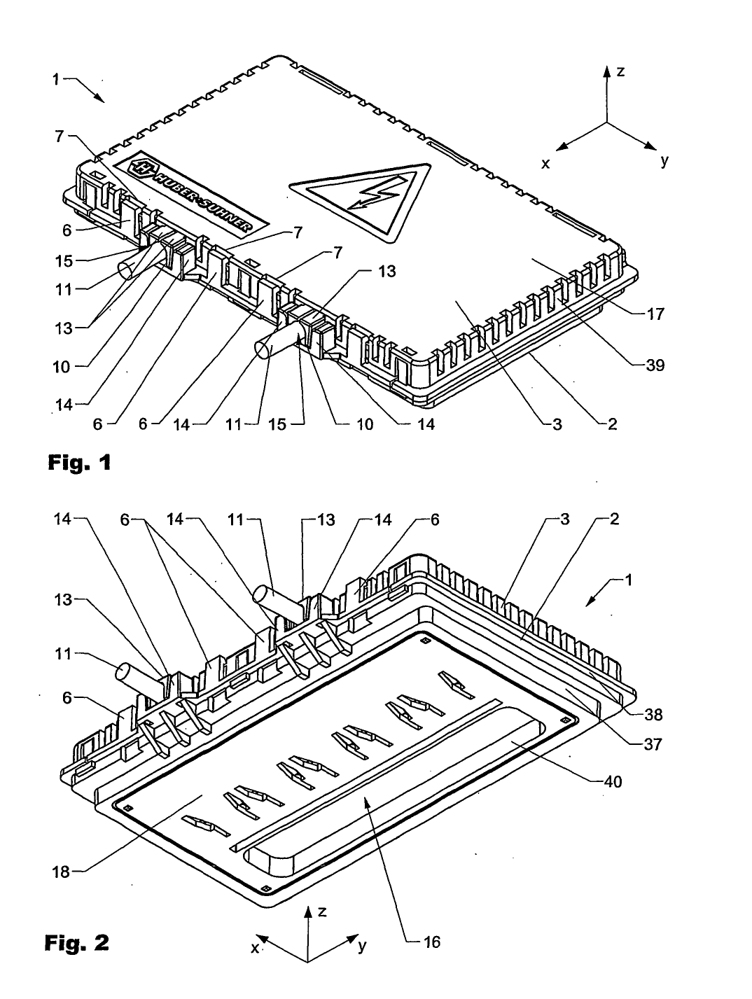

FIG. 2 the connection box as in FIG. 1 in a perspective representation from obliquely in front and below;

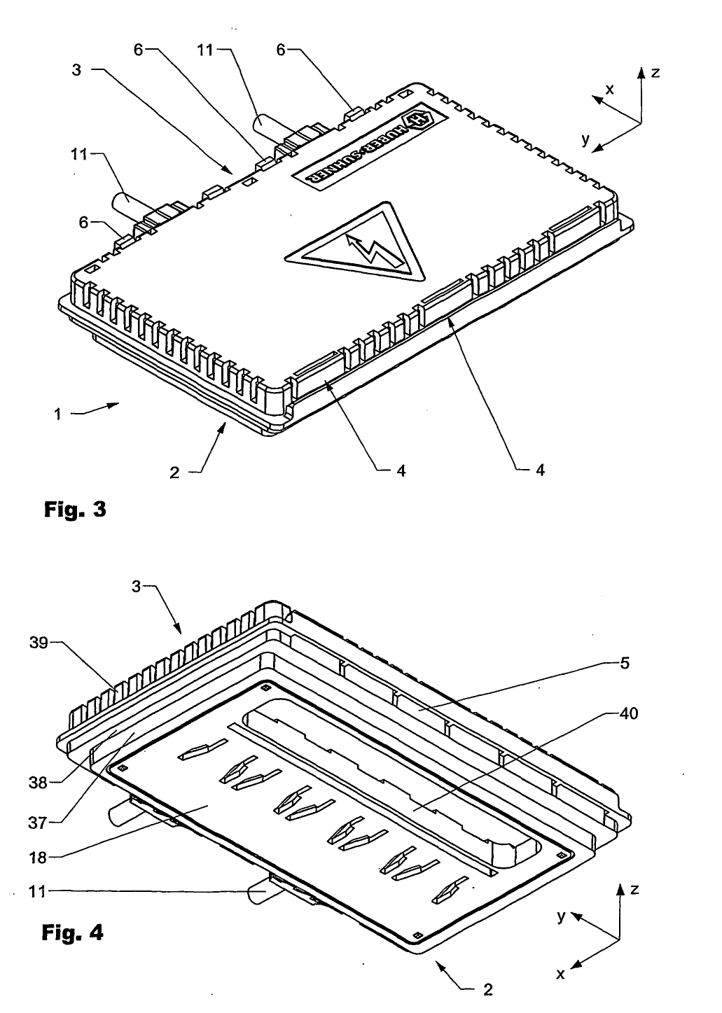

FIG. 3 the connection box as in FIG. 1 in a perspective representation from obliquely above and behind;

FIG. 4 the connection box as in FIG. 1 in a perspective representation obliquely below and behind;

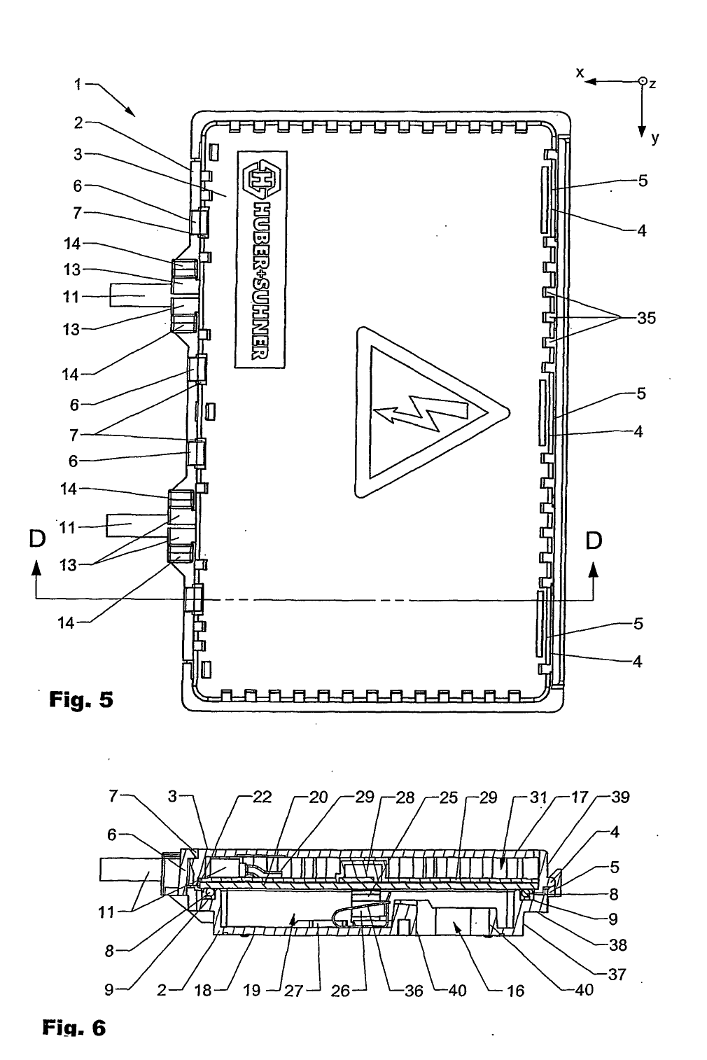

FIG. 5 shows the connection box as in FIG. 1 in a top view;

FIG. 6 shows a sectional view along the line DD in FIG. 5;

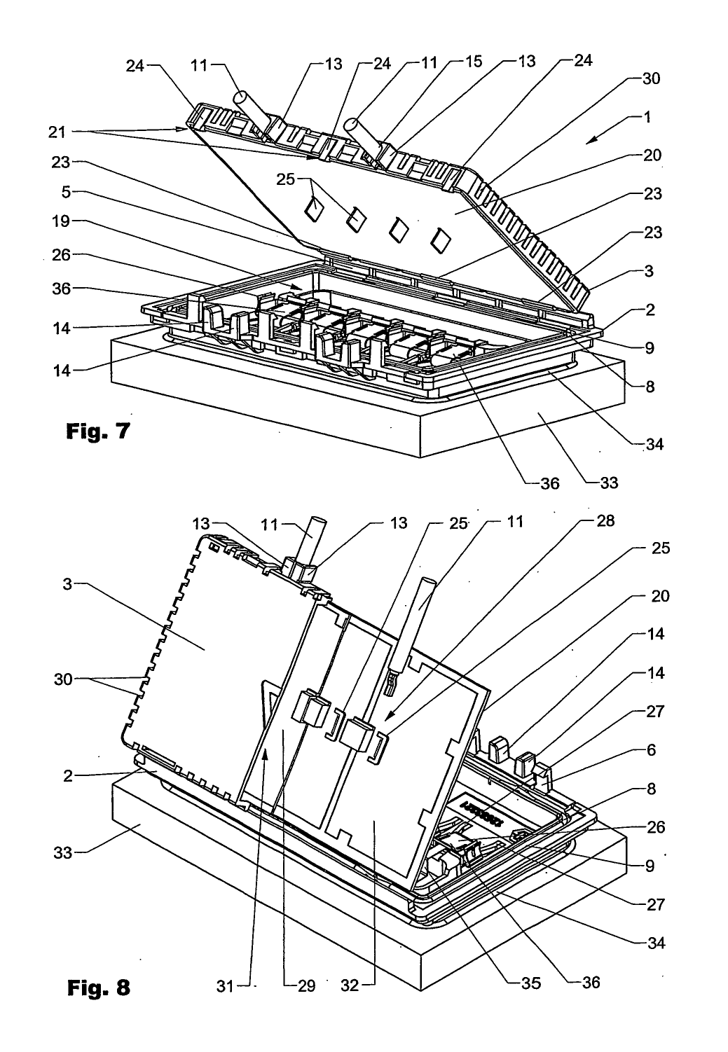

FIG. 7 shows the connection box as in FIG. 1 from obliquely in front and above mounted on a solar cell with open housing top;

FIG. 8 shows the connection box as in FIG. 1 from obliquely behind and above mounted on a solar cell and with housing top cut open.

FIG. 1 shows a connection box 1 in a perspective representation from obliquely in front and above. FIG. 2 shows the connection box 1 from FIG. 1 in a perspective representation from obliquely in front and below. FIG. 3 shows the same connection box from obliquely above and behind, and FIG. 4 shows obliquely below and behind. FIG. 5 shows the connection box 1 in a top view, and FIG. 6 shows a section along the line DD in FIG. 5. Corresponding elements/areas are given the same numbers in all figures.

In FIGS. 1 to 6, a housing base 2 with a housing top 3 set on it can be recognized. In the rear area the housing top 3 has pivot studs 4, which engage with corresponding bearing openings 5 in the housing base 2 (cf. FIG. 6 among others). In the front area of the housing base 2, snap hooks 6 are fitted, which engage with corresponding snap hook openings 7 of the housing top 3. By the number and arrangement of the snap hooks 6, it is achieved that the housing of the connection box can only be opened with a tool developed specifically for this. In the embodiment shown, the pivot studs 4 and the bearing openings 5 are designed such that the housing top 3 can be taken off the housing base 2, provided it in the front area the snap hooks 6 are undone and this front area is slightly raised compared to the pivot studs 4. Alternatively or in supplement, snap hooks (not shown in detail) can be developed on the housing top 3, which fit in corresponding counter-openings in the area of the housing base. An embodiment in which the snap hooks is developed on the housing top, offers the advantage that when a snap hook is broken off, the housing base does not have to be replaced. Depending on the embodiment and application area, it is possible for example to connect the housing top 3 to the housing base with only snap connections and/or screw connections. In these embodiments, there is no need in some circumstances for pivot studs and corresponding bearing openings. Other forms of connection, e.g. locking pins and seals, are possible.

The housing top 3 of the embodiment shown has cable openings 10 for external wiring 11. The cable openings 10 are developed as clamps 12 which have two jaws 13, which engage, when the housing top 3 is closed, with corresponding counter-jaws 14 developed on the housing base 2, and are pressed by these against an outer coating 15 of the external wiring 11.

The housing base 2 and likewise the housing top 3 of the embodiment shown are essentially concave in design. The housing base 2 here has a bottom 18, a surrounding border 37 (side wall) with a flange 38 protruding outwards. The housing base 2 as a whole or part thereof, e.g. a subarea of the bottom 18, can be designed as a pedestal for the non-electrical connection or the attachment to a solar cell, and have corresponding linking and connecting elements. The housing base 2 is open on the side opposite the bottom 18 and encloses a first interior area 19. The housing top 2 has a lid 17 and a surrounding border 39 (side wall). The housing top 3 is open on the side opposite the bottom 18 and encloses a second interior area 31. The first and second interior areas 19, 31 form the interior space (cavity) of the connection box. Between the first and second interior areas 19, 31 in the closed position, a circuit board 20 is embedded, among other things, which in the embodiment shown extends across the entire interior space and serves as the outer wall of the second interior area 31 of the housing top 3. The electrical or electronic components 28 disposed in the interior report 31 are thereby protected.

As can be seen in FIGS. 2, 4 and 6, the housing base 2 has a connector opening 16 with a surrounding border 40, through which electrical connectors 35 are led from solar cells into the interior space of the connection box. In the interior space of the connection box, multiple electrical connectors (clip contacts) 36 disposed side by side are here assigned to the connector opening 16. A bottom 18 of the housing base 2 is here designed as a mounting pedestal, in that it is suitable for the attachment of the connection box 1 by means of a suitable adhesive to a flat surface, e.g. the surface (reverse side) of a solar cell. For this the bottom 18 is relatively large in area and made flat, and has a surrounding ridge, so that an adhesive 34, e.g. silicone jointing compound, can be distributed around the connector opening 16 to the ridge as maximum. The connection box 1 is then set on a surface e.g. over the connector area of a solar cell and, if necessary, fixed until the adhesive sets. The adhesive can simultaneously serve as a jointing compound or filler element, and can be filled into the connector opening 16 up to the height of the surrounding border 40, provided neither the cooling properties nor the closing properties of the connection box are impaired. The connection box 1 can also be attached in a different way if necessary, provided the function is not impaired.

In the embodiment shown, a seal 8 is disposed between the housing base 2 and the circuit board 20 in a surrounding groove 9 of the housing base 2. As can best be seen from FIG. 6, when the housing top 3 is closed the seal 8 is nipped between the reverse side of the circuit board 20 and the housing base 2 in such a way that the first opening (cavity) 19 in the interior is sealed. Any contacts and electrical/electronic components disposed in the first cavity 19 are thereby protected from outside influences. In the embodiment shown, the seal 8 is laid in the groove 9. If necessary, there is alternatively or in supplement the possibility of spraying sealing elements (not shown in detail) in the housing base and/or on the housing top 3.

As can best be seen in FIGS. 7 and 8, the housing top 3 is designed such that it is suitable for receiving a circuit board 20. For this purpose the housing top 3 has retaining means 21 for the reception. In the embodiment shown, these are a support 22 and, disposed distanced from the support 22, relief cuts 23 and snap elements 24, which are disposed such that the circuit board 20 can be snapped into them separably or inseparably. After being snapped in, the circuit board 20 together with the housing top 3 forms one unit, which can be set prefabricated into the housing base 2 and removed from this again. The external wiring 11 runs through the cable openings 10 and the jaws 13, which in this open position do not yet exert pressure on the outer coating 15 of the wiring 11. Only when the housing top 3 is closed, and the jaws 13 come to rest between the counter-jaws 14, is the cable securely held, so that the risk of unwanted withdrawal is reduced.

On its outward-facing underside, the circuit board 20 has pin-shaped first electrical contacts 25, which, when the housing top 3 of the connection box 1 is closed, interact electrically conductively with second electrical contacts 26, which are disposed in the housing base 2. As can be seen, the first electrical contacts 25 are here pin-shaped and developed protruding from the underside of the circuit board 20. The second electrical contacts 26, which are inside the housing base 2, are developed in clamp form, and disposed in such a way that the first electrical contacts 25 engage with them on closure. Both the first and the second electrical contacts are formed from sheet metal. While the first electrical contacts are attached to the circuit board 20, the second electrical contacts are snapped into corresponding mountings 27 developed on the bottom of the housing base 2. The second electrical contacts 26 are assigned clip contacts 36 in effective connection: In the embodiment shown, the second electrical contacts 26 and the clip contacts 36 are formed as a piece from sheet metal.

In FIG. 8 a part of the housing top 3 is cut away, to enable a view of the circuit board 20 and electrical and/or electronic components 28 disposed thereon. The electronic components 28 are effectively connected to the first electrical contacts 25 here running through the circuit board 20 and/or to the external wiring 11. The housing top 3 has cooling openings (louvers) 30, through which a cooling medium, e.g. air, can flow into a second cavity 31 between the circuit board 20 and the housing top 3 in order to cool the components 28 and the circuit board 20. To achieve better cooling, the circuit board 20 and/or one of the housing parts 2 or 3 can be developed at least partially as a cooling element 32. At least areas of the circuit board 20 and/or the components 28 and/or the external wiring 11 can if necessary be supplied with a protective layer 29, for example in the form of an insulating lacquer, which has an electrically insulating effect and/or protects against outside influences.

The connection box 1 is shown in FIGS. 7 and 8 disposed on a solar cell 33. The housing base 2 is attached with an adhesive 34 on a surface of the solar cell 33, and effectively connected with electrical connectors 35 to the solar cell 33. For this, the electrical connectors 35 of the solar cell 33 are nipped into clip contacts 36 of the second electrical contacts 26. The clip contacts 36 are here formed and disposed in such a way that on closing or in the closed state of the connection box there is the best possible clamping effect, and the electrical contacts 35 of the solar cell 33 are thereby mechanically secured against separation, so that there is no need for filling of the connector opening 16 to fix the electrical contacts 35.

1. A connection box (1) comprising:
a housing base (2) and a housing top (3) wherein the housing top (3) has retaining means (21) for receiving a circuit board (20).

2. The connection box (1) as claimed in claim 1, wherein the housing top (3) has means for connecting external wiring (11).

3. The connection box (1) as claimed in claim 1, wherein the housing base (2) further comprises a mounting pedestal (2) and/or means for effective connection with a mounting pedestal (2).

4. The connection box (1) as claimed in claim 1, wherein the retaining means (21) of the housing top (3) for receiving the circuit board (20) comprises a support (22), a relief cut (23) and/or snap elements (24).

5. The connection box (1) as claimed in claim 1, wherein the circuit board (20) generally extends across the entire opening of the housing top (3).

6. The connection box (1) as claimed in claim 5, wherein the circuit board is disposed between the housing base (2) and the housing top (3).

7. The connection box (1) as claimed in claim 1, wherein a seal (8) is disposed between the circuit board (20) and the housing top (3) and/or the housing base (2).

8. The connection box (1) as claimed in claim 1, wherein the housing top (3) and the circuit board (20) form a modular unit.

9. The connection box (1) as claimed in claim 1, wherein the circuit board (20) has electrical/electronic components (28).

10. The connection box (1) as claimed in claim 9 and further connected with a solar cell, wherein the electrical/electronic components (28) are mounted on the side of the circuit board (20) which is turned away from the solar cell (33).

11. The connection box (1) as claimed in claim 8, wherein the electrical/electronic components (28) are in the an interior area (31) of the housing top (3).

12. The connection box (1) as claimed in claim 1, wherein the housing base (2) has an opening (16) for receiving electrical connectors (35) of a solar cell (33).

13. The connection box (1) as claimed in claim 12, wherein the opening (16) is fitted in the a housing bottom (18) of the housing base.

14. The connection box (1) as claimed in claim 1, wherein the circuit board (20) interacts with the housing base (2) through first and second electrical contacts (25, 26), which make an effective connection with the housing base (2) when the housing top (3) is closed.

15. The connection box (1) as claimed in claim 1, wherein the housing top (3) has cooling openings (30).

16. The connection box (1) as claimed in claim 1, wherein the circuit board (20) is designed as a thermal separation element.

17. A connection box (1) for use with a solar cell comprising:
a housing base (2) and a housing top (3) wherein the housing top (3) has retaining means (21) for receiving a circuit board (20) and at least one of the housing base (2) and the housing top (3) has an opening (16) for receiving electrical connectors (35) of the solar cell (33).

18. The connection box (1) as claimed in claim 17, wherein the circuit board (20) interacts with the housing base (2) through first and second electrical contacts (25, 26), which make an effective connection with the housing base (2) when the housing top (3) is closed.
